(19) United States
(12) Patent Application Publication
(10) Pub. No.: US 2020/0174048 A1
(43) Pub. Date: Jun. 4, 2020

(54) SENSOR VOLTAGE PHASE ANGLE CORRECTION

(71) Applicant: SENTIENT ENERGY, INC., Burlingame, CA (US)

(72) Inventors: Nasahn Frank READER, Burlingame, CA (US); William Ed PIERCE, Menlo Park, CA (US)

(21) Appl. No.: 16/700,888

(22) Filed: Dec. 2, 2019

Related U.S. Application Data
(60) Provisional application No. 62/773,888, filed on Nov. 30, 2018.

(51) Int. Cl. G01R 25/00

(52) U.S. Cl. CPC G01R 25/005

(57) ABSTRACT

A monitoring system is provided for correcting phase angle errors using an accurate current sensor such as a current transformer, or Rogowski coil. Using an accurate source of time and communication, such as a cellular or mesh radio, this correction can then be applied across a fleet of sensors within a range (governed by wave propagation speed of electricity) and between transformers.

### CROSS REFERENCE TO RELATED APPLICATIONS

This application claims the benefit of U.S. Provisional Patent Application No. 62/773,888, filed Nov. 30, 2018, titled “Sensor Voltage Phase Angle Correction”, the contents of which are incorporated by reference herein.

### INCORPORATION BY REFERENCE

All publications and patent applications mentioned in this specification are herein incorporated by reference to the same extent as if each individual publication or patent application was specifically and individually indicated to be incorporated by reference.

### FIELD

The present application relates generally to distribution line monitoring, sensor monitoring, and sensing and identifying electrical characteristics of a power distribution line. More specifically, the present invention relates to systems and methods for correcting the phase angle error of line monitoring sensors that measure the voltage of power distribution lines.

### BACKGROUND

Utilities have various reasons for needing to know an accurate angle between voltage and current. Primarily, this is for the purpose of measuring Power Factor and Real and Reactive Power. Adequate reactive power is essential to the health of the grid.

Various types of equipment attempt to monitor the voltage of a power line without a ground reference. These include electric field sensors, phase-to-phase measurements, or other types of sensors to approximate the voltage signal. The approximations produce signals that deviate from the true voltage of a conductor in both phase and amplitude. In the case of an electric field sensor for instance, these errors are due to both the effects of cross coupling from adjacent conductors and environmental conditions.

### BRIEF DESCRIPTION OF THE DRAWINGS

The novel features of the invention are set forth with particularity in the claims that follow. A better understanding of the features and advantages of the present invention will be obtained by reference to the following detailed description that sets forth illustrative embodiments, in which the principles of the invention are utilized, and the accompanying drawings of which:

FIG. 1A is a typical over-head three-phase power distribution system utilizing a cross-bar mounted on pole for mechanical positioning of the conductors. Alternate patterns of parallel conductor routing are sometimes used. Power distribution line monitoring devices (102,104,106) are attached to the power lines typically using a standard lineman's shotgun hotstick (116) for easy deployment with necessitating turning off power in the lines.

FIGS. 1B and 1C show a schematic representation of a monitoring sensor in the closed (1B) and open (1C) positions. The open position facilitates mounting the monitoring sensor on a power line. The sensor remains on the power line in the closed (1B) position.

FIG. 2 represents a power triangle which illustrates reactive power as a complex vector consisting of real power (Watts) and reactive or apparent power (vars).

FIG. 3 is a phase angle illustration showing the relationship between voltage, current, power, and average power.

FIG. 4 is an illustration showing capacitor bank engaging waveforms and phase angle without phase angle correction.

FIG. 5 is an illustration showing capacitor bank engaging power analysis without phase angle correction.

FIG. 6 is an illustration showing capacitor bank engaging waveforms and phase angle with phase angle correction.

FIG. 7 is an illustration showing capacitor bank engaging power analysis with phase angle correction.

FIG. 8 illustrates a pair of in-phase and quadrature waveforms at the fundamental frequency providing a reference against which phase measurements are made.

FIG. 9 is a flowchart illustrating one method for correcting phase angle measurement errors that result from cross coupling.

### SUMMARY OF THE DISCLOSURE

A method of collecting and characterizing phase measurements of a power network is provided, comprising receiving current magnitude and phase measurements from a plurality of line monitoring devices prior to an active switching event on the power network, receiving current magnitude and phase measurements from the plurality of line monitoring devices after the active switching event on the power network, estimating optimal phase angles for each phase of the power network, determining an error correction value for the phase measurements, and correcting the estimated optimal phase angles for each phase of the power network with the error correction value.

In some examples, the method further comprises collecting current magnitude and electric field phase measurements from the power network with the plurality of line monitoring devices.

Collecting the phase measurements can comprise, for example, measuring an electric field of conductors of the power network, measuring a current of conductors of the power network, or measuring a voltage of conductors of the power network.

In some embodiments, the active switching event is the result of a capacitor bank operating on the power network, a recloser operating on the power network, or a switch operating on the power network.

In some embodiments, the optimal phase angles are spaced 120 degrees apart.

In one embodiment, estimating optimal phase angles for each phase of the power network further comprises rotating each of the phase measurements by a rotation angle that places a B-phase value at 180 degrees, averaging the rotated B-phase value, a rotated A-phase value, and a rotated C-phase value, determining a new estimate for the B-phase value from the averaged rotated B-phase, A-phase, and C-phase values, determining a new estimate for the A-phase value and the C-phase value from the new estimate for the B-phase value, and removing the rotation angle from each of the new estimates.

In some embodiments, the correction value is a constant phase error between an approximated voltage and a true voltage.

A non-transitory computing device readable medium having instructions stored thereon is also provided, wherein the instructions are executable by a processor to cause a computing device to perform a method comprising receive current magnitude and phase measurements from a plurality of line monitoring devices prior to an active switching event on the power network, receive current magnitude and phase measurements from the plurality of line monitoring devices after the active switching event on the power network, estimate optimal phase angles for each phase of the power network, determine an error correction value for the phase measurements, and correct the estimated optimal phase angles for each phase of the power network with the error correction value.

A power line monitoring system is also provided, comprising a plurality of line monitoring devices configured to collect current magnitude and phase measurements for each phase of a power network before and after an active switching event, and a remote computing device configured to receive the current magnitude and phase measurements from the plurality of line monitoring devices, the remote computing device being configured to estimate optimal phase angles for each phase of the power network, determine an error correction value for the phase measurements, and correct the estimated optimal phase angles for each phase of the power network with the error correction value.

### DETAILED DESCRIPTION

The present disclosure provides line monitoring sensors and methods that correct phase angle errors due to both the effects of cross coupling from adjacent conductors and environmental conditions using an accurate current sensor such as a current transformer, or Rogowski coil in conjunction with an inaccurate voltage measurement. Using an accurate source of time and communication, such as a cellular or mesh radio, this correction can then be applied across a fleet of sensors within a range (governed by wave propagation speed of electricity) and between transformers.

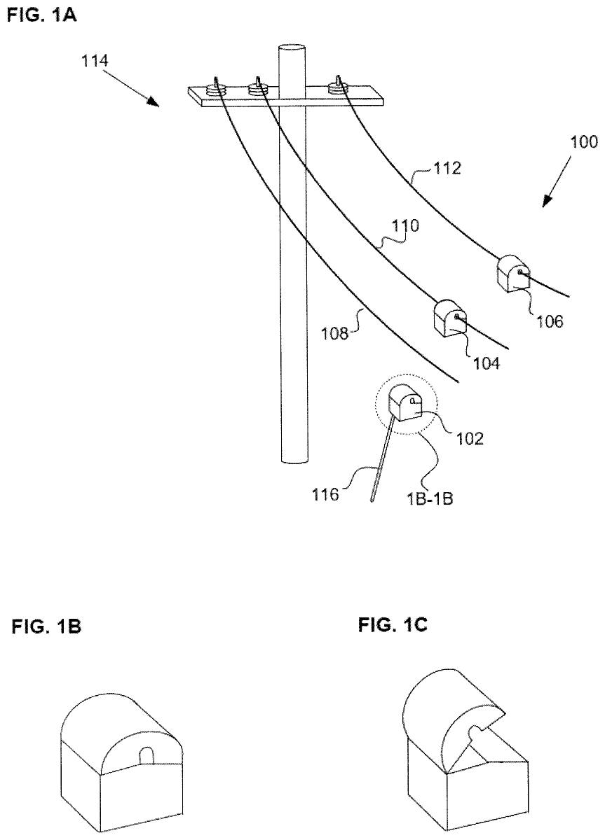

Power line monitoring devices and systems described herein are configured to measure the currents and electric fields of power grid distribution networks. Referring to FIG. 1A, monitoring system 100 comprises monitoring devices 102, 104, and 106 mounted to power lines 108, 110, and 112, respectively, of power distribution network 114. The power distribution network can be a three phase AC network, or alternatively, a single-phase network, for example. The power distribution network can be any type of network, such as a 60 Hz North American network, or alternatively, a 50 Hz network such as is found in Europe and Asia, for example. Power distribution networks, such as in the United States, typically operate at a medium voltage (e.g., 4 kV to 65 kV or higher) to reduce the energy lost during transmission over long distances. The monitoring devices can also be used on high voltage “transmission lines” that operate at voltages higher than 65 kV.

Monitoring devices 102, 104, and 106 can be mounted on each power line of a three-phase network, as shown, and can be configured to monitor, among other things, current flow in the power line and current waveforms, conductor temperatures, ambient temperatures, vibration, wind speed and monitoring device system diagnostics. In some embodiments, a fourth sensor can be mounted on the ground line near the three phase lines. In additional embodiments, multiple sensors can be used on a single phase line. The monitoring devices can be mounted quickly and easily via a hot-stick 116, and can harvest energy from the power lines for operation with or without additional supplemental power (e.g., include batteries or solar panels). The monitoring devices can further include wireless transmission and receiving capabilities for communication with a central server and for communications between each monitoring device. Installation of a three monitoring device array can be placed and configured by a single linesman with a hot-stick and a bucket truck in less than 20 minutes. Monitoring device communication with the installation crew can be enabled during the installation process to provide immediate verification of successful installation. FIG. 1B illustrates a monitoring device in a closed/clamped configuration, and FIG. 1C shows the monitoring device in an opened/installation configuration. It should be understood that the device is opened into the installation configuration during installation on power lines, then closed around the line in the clamped configuration prior to operation.

Furthermore, monitoring devices 102, 104, and 106 are configured to also measure the electric field surrounding the power lines, to record and analyze event/fault signatures, and to classify event waveforms. Current and electric field waveform signatures can be monitored and catalogued by the monitoring devices to build a comprehensive database of events, causes, and remedial actions. In some embodiments, an application executed on a central server can provide waveform and event signature cataloguing and profiling for access by the monitoring devices and by utility companies. This system can provide fault localization information with remedial action recommendations to utility companies, pre-emptive equipment failure alerts, and assist in power quality management of the distribution grid.

Monitoring devices 102, 104, and 106 can comprise sensing elements, a power supply, a battery, a microprocessor board, and high powered communication systems (not shown) disposed within a robust mechanical housing designed for severe service conditions. The monitoring devices are configured to withstand temperatures ranging from −40 to +85 C, EMI and ESD immunity, current and voltage impulse resistance, driving rain and precipitation and salt fog survival. A typical embodiment of the monitoring devices is configured to operate continuously on power lines carrying up to 800 A_{RMS} operating current with full functionality. Full functionality is also maintained during line fault current events up to 10 kA_{RMS} and of limited time duration.

The monitoring devices can be configured to communicate wirelessly through a distribution network to the power utilities sensor control and distribution automation (SCADA) system. In some embodiments, the monitoring devices operate at differing powers with a custom designed omni-directional antenna. When mounted to typical power grid distribution networks, the monitoring devices are located approximately 30 feet above ground level and typically above tree tops, providing for a very substantial effective range of communication. In addition to two-way network communications for data packets and setting operational setpoints, the monitoring devices can be configured for wireless device firmware upgrades for long term functionality.

In another embodiment, the monitoring devices can be configured to communicate wirelessly through a cellular network with dedicated cellular chips on each monitoring device.

Provided herein are systems, methods, and techniques for correcting a phase angle error of sensors configured to measure the voltage of an electric utility line. Line monitoring devices described herein can use the properties of active or switched grid equipment such as a capacitor bank, recloser, or switch to provide a phase angle correction. The systems and methods described herein detail phase angle correction methodologies on a sensor or sensors deployed on a utility circuit capable of detecting capacitor bank engagement or other active switching operations. The Capacitor bank based correction shall be described in detail, but the principles described can be utilized for the properties of other equipment.

Capacitor banks are used in the electric grid to provide a local source of reactive power in order to support the proper grid voltage and to improve the power factor. AC power flow consists of real power (Watts) and reactive power (vars). These can be viewed as the real and imaginary parts of a complex vector, where θ is the angle between the fundamental voltage and current waves, and the apparent power S is the magnitude of the vector.

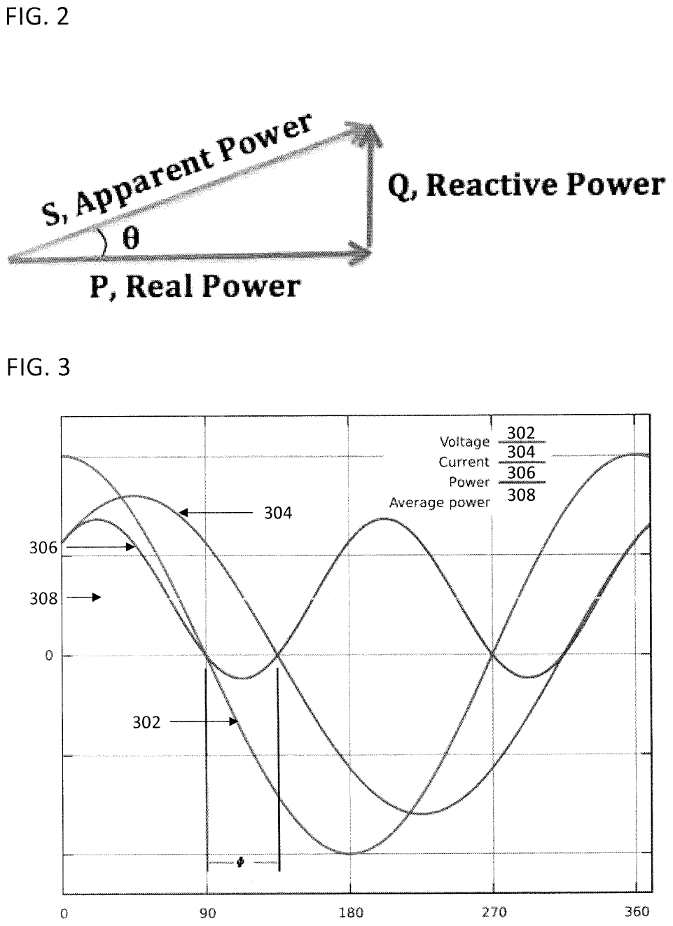

An ideal capacitor bank provides only reactive power, and no real power. Thus, for the time immediately before and after the capacitor bank engagement, any sensor upstream measuring current and true voltage would see no change to real power. By using this fact, one can correct the phase angle error of a voltage-approximating sensor by computing the required phase angle to produce a constant real power result. This is not a perfect correction, as small voltage changes may affect the real power consumption of the circuit. FIG. 2 represents a power triangle which illustrates reactive power as a complex vector consisting of real power (Watts) and reactive or apparent power (vars).

FIG. 3 is a phase angle illustration showing the relationship between voltage 302, current 304, power 306, and average power 308. The phase angle error can be determined by solving or approximating e in the following equation:

cos(∅+e)*S₀=cos(∅′+e)*S₁, Equation 1

where ∅ and ∅′ are the measured phase angles between the approximated voltage and the true current prior to and after capacitor bank engagement, respectively. S₀ and S₁ are the apparent powers before and after capacitor bank engagement, respectively. The error value e is the constant phase error between the approximated voltage and the true voltage. Repeating this process over multiple capacitor bank engagements over many days and averaging the results will further improve the estimation of the correction value e. Note that a voltage amplitude measurement is not required when solving for e since the voltage magnitude appears on both sides of the equation and will therefore cancel. Once e is calculated it can be applied to correct the phase angle of the approximate voltage waveform.

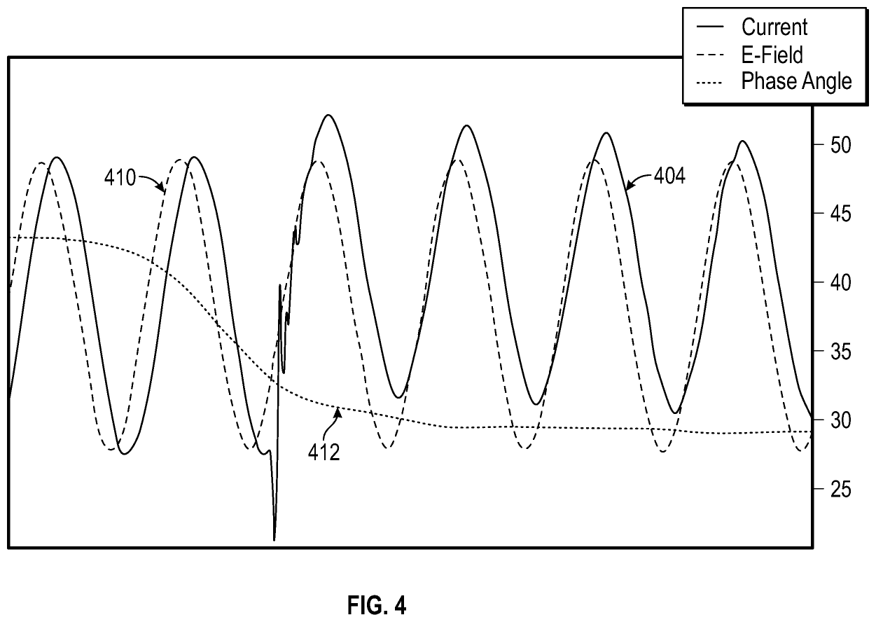

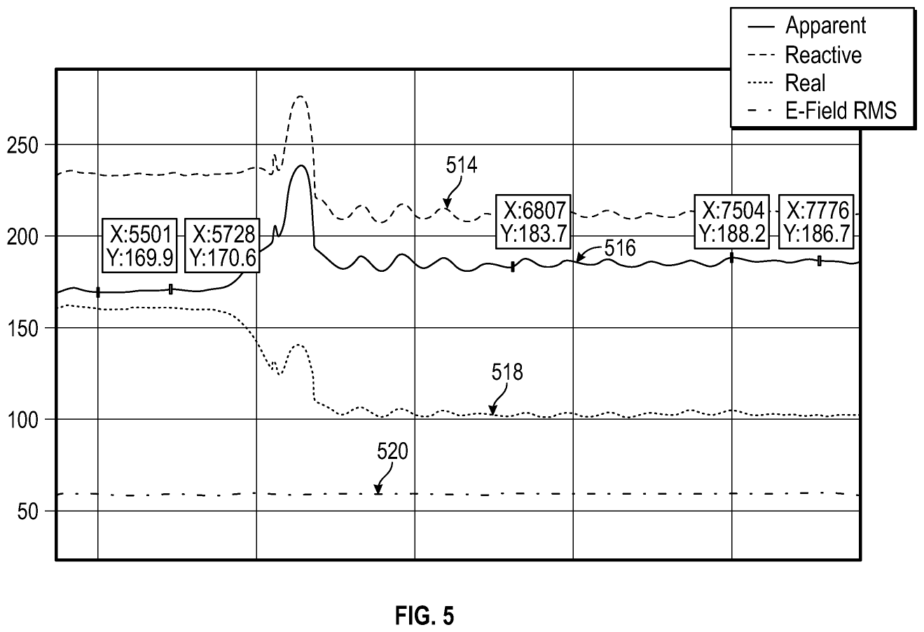

FIGS. 4-5 show a capacitor bank engaging as measured by a line-monitoring device with an electric field sensor. FIG. 4 shows capacitor bank engaging waveforms and phase angle, before correcting the phase angle. The plot of FIG. 4 illustrates the relationship between current 404, electric field 410, and phase angle 412. FIG. 5 shows a power analysis of a capacitor bank engaging and illustrates the relationship between apparent power 514, reactive power 516, real power 518, and electric field RMS 520.

Referring to FIG. 4, according to the line monitor, the current phase angle relative to the approximated voltage was 43 degrees before the cap bank switch and 29 degrees after. This corresponds to a 9.4% increase in real power, as illustrated in FIG. 5. Solving Equation 1 yields a correction value of 13.5 degrees.

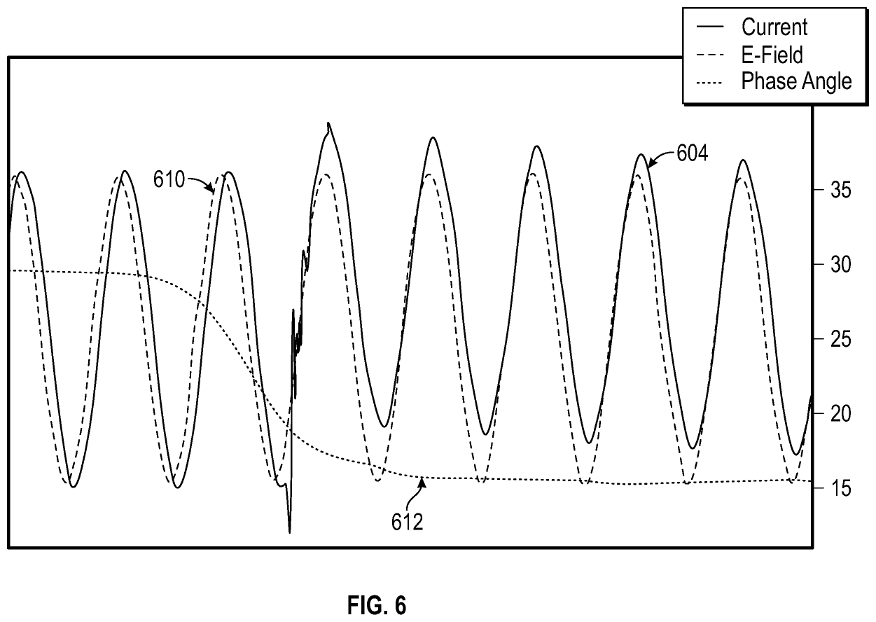

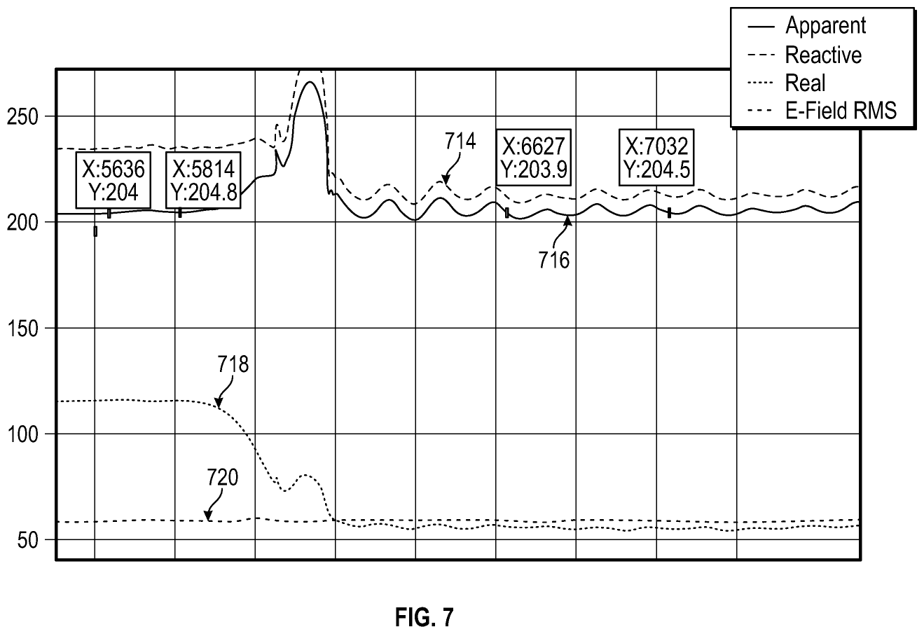

FIGS. 6-7 illustrate a capacitor bank engaging as measured by a line-monitoring device with an electric field sensor, after correcting the phase angle with the correction value calculated above. The plot of FIG. 6 illustrates the relationship between current 604, electric field 610, and phase angle 612. FIG. 7 shows a power analysis of a capacitor bank engaging and illustrates the relationship between apparent power 714, reactive power 716, real power 718, and electric field RMS 720. Applying the above correction of 13.5 degrees to the electric field wave results in the diagrams shown in FIGS. 6-7. After solving for the ideal capacitor and applying the phase shift the new phase angle change is 30 degrees to 15 degrees, lagging.

### Multi-phase Correction

When cap bank switching disturbances are recorded on all three phases simultaneously (as will be typical for three-phase systems), the data can be combined to provide an improved estimate of the e-field error on each phase. This data fusion relies on the reasonable assumptions that the true voltage phases on the three conductors are precisely 120 degrees apart, and that the absolute e-field phase errors are less than 30 degrees. Note also that clocks can be synchronized for the three sensors (e.g., using GPS) so that the e-field phase measurements across conductors can be compared meaningfully.

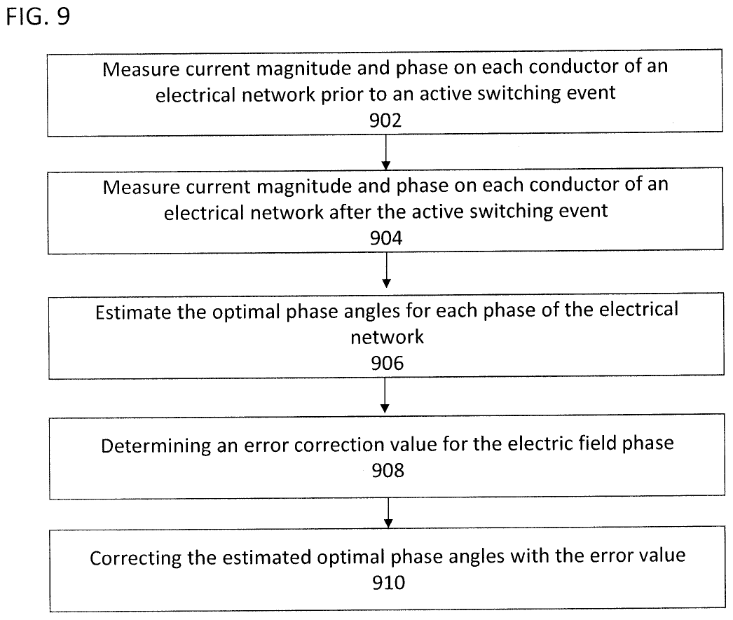

The estimation of the e-field phase error proceeds in the following steps, as illustrated the flowchart of FIG. 9:

At steps 902 and 904, the current magnitude and electric field phases of an electrical network can be measured on each of the conductors of the electrical network before and after an active switching event on the electrical network. The measurements can be done using, for example, the line monitoring devices described herein for each conductor of the network. As further described herein, the active switching event on the electrical network can be the result of a capacitor bank, recloser, or switch operating on the network.

Next, at step 906, using only the measured e-field phases on each of the conductors, the one or more of the line monitoring sensors, or a central computing processor or server, can calculate the optimal estimate (in a least squared sense) of the conductor voltage phase angles that are 120 degrees apart.

One example of determining the optimal estimate of the phase angles can be, for example, implemented by rotating the three measured e-field phases by the angle δ that places the B-phase value at 180 degrees. For the conventional phase orientation, this will place the A-phase near 60 and the C-phase near 300. (For the opposite phase orientation, the necessary modification to this algorithm is straightforward.) Next, the average of the three values can be taken: A-phase+120, B-phase, C-phase−120. This average will be the new estimate for the rotated B-phase. The A-phase can then be calculated to be 120 degrees less than the rotated B-phase estimate, and the C-phase can be calculated to be 120 degrees more than the rotated B-phase estimate. Finally, the original rotation of δ degrees can be undone to arrive at the estimated phase angles: ∅_{EA}, ∅_{EB}, ∅_{EC}. These estimates capture the 120-degree separation constraint between the three phases without using any additional information about the cap bank switching event.

Since the phase angle estimates from step 904 are 120 degrees apart, and since the final estimates for the voltage phases will be 120 degrees apart, the estimated error correction will be the same for all three phases. Thus, at step 908, the system can capture the constant-real-power constraint for the cap bank switching event by finding/determining a single error value e that best solves the following equations:

S_{A}*cos(∅_{EA}−∅_{IA}+e)=S′_{A}*cos(∅_{EA}−∅′_{IA}+e) Equation 2

S_{B}*cos(∅_{EB}−∅_{IB}+e)=S′_{B}*cos(∅_{EB}−∅′_{IB}+e) Equation 3

S_{C}*cos(∅_{EC}−∅_{IC}+e)=S′_{C}*cos(∅_{EC}−∅′_{IC}+e) Equation 4

Here, S_{K} and ∅_{IK} (for k=A, B, C) are the current magnitude and phase of conductor k before the cap bank switch. S′_{K} and ∅′_{IK} denote corresponding values after the cap bank switch. As described above, the value e is the constant phase error between the approximated voltage and the true voltage.

To solve for the unknown error e, standard numerical techniques are used to find the value that minimizes:

$${\sum }_{k = A , B , C} {[ {S}_{k} * cos ( {φ}_{Ek} - {φ}_{Ik} + e ) - {S}_{k}^{′} * cos ( {φ}_{Ek} - {φ}_{Ik}^{′} + e ) ]}^{2} \qquad Equation 5$$

Finally, at step 910, the error e can be applied to the estimated optimal phase angles to yield final estimates for the voltage phases: ∅_{EA}+e, ∅_{EB}+e, ∅_{EC}+e. The error e is therefore used to correct the estimated optimal phase angles to accurately reflect the true phase angles on the electrical network.

### Correcting Other Sensors

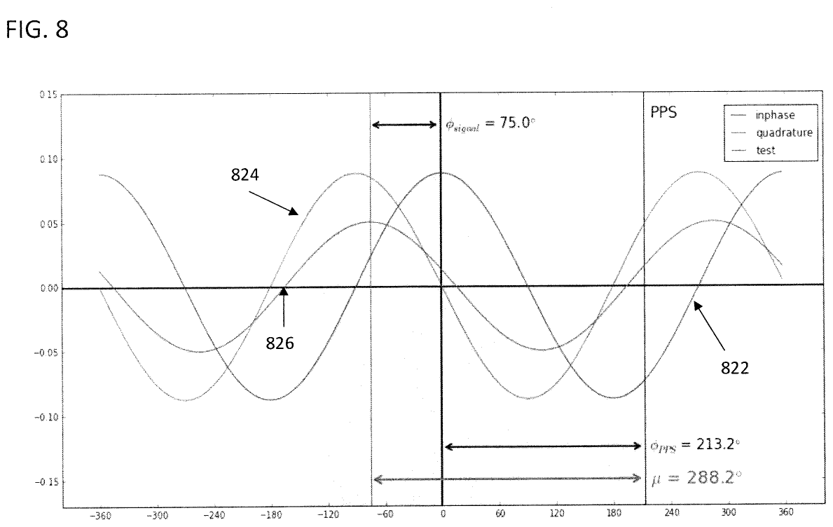

A reference unit or set of units, for 3-phase systems—one on each conductor/phase, can correct sensors proximal to the reference(s). The corrected unit on a given three-phase power line-phase takes a signature of the voltage phase relative to a time reference, then communicates that signature to the other units in the fleet or a coordinating backend for the same line-phase. The signature can be derived by capturing the phase angle relative to a test waveform, for example the time between the calculated zero-phase point of the test waveform and a GPS-based second marker. This is illustrated in FIG. 8, where a pair of in-phase 822 and quadrature 824 waveforms and a test waveform 826 at the fundamental frequency provide a reference against which phase measurements are made. On receipt of the signature, the proximal line monitoring devices can adjust their voltage measurement phase angles by accounting for the reported phase offset between the true line voltage and the shared, accurate time reference.

As for additional details pertinent to the present invention, materials and manufacturing techniques may be employed as within the level of those with skill in the relevant art. The same may hold true with respect to method-based aspects of the invention in terms of additional acts commonly or logically employed. Also, it is contemplated that any optional feature of the inventive variations described may be set forth and claimed independently, or in combination with any one or more of the features described herein. Likewise, reference to a singular item, includes the possibility that there are plural of the same items present. More specifically, as used herein and in the appended claims, the singular forms “a,” “and,” “said,” and “the” include plural referents unless the context clearly dictates otherwise. It is further noted that the claims may be drafted to exclude any optional element. As such, this statement is intended to serve as antecedent basis for use of such exclusive terminology as “solely,” “only” and the like in connection with the recitation of claim elements, or use of a “negative” limitation. Unless defined otherwise herein, all technical and scientific terms used herein have the same meaning as commonly understood by one of ordinary skill in the art to which this invention belongs. The breadth of the present invention is not to be limited by the subject specification, but rather only by the plain meaning of the claim terms employed.

What is claimed is:

1. A method of collecting and characterizing phase measurements of a power network, comprising:
receiving current magnitude and phase measurements from a plurality of line monitoring devices prior to an active switching event on the power network;
receiving current magnitude and phase measurements from the plurality of line monitoring devices after the active switching event on the power network;
estimating optimal phase angles for each phase of the power network;
determining an error correction value for the phase measurements; and
correcting the estimated optimal phase angles for each phase of the power network with the error correction value.

2. The method of claim 1, further comprising collecting current magnitude and electric field phase measurements from the power network with the plurality of line monitoring devices.

3. The method of claim 2, wherein collecting the phase measurements comprises measuring an electric field of conductors of the power network.

4. The method of claim 2, wherein collecting the phase measurements comprises measuring a current of conductors of the power network.

5. The method of claim 2, wherein collecting the phase measurements comprises measuring a voltage of conductors of the power network.

6. The method of claim 1, wherein the active switching event is the result of a capacitor bank operating on the power network.

7. The method of claim 1, wherein the active switching event is the result of a recloser operating on the power network.

8. The method of claim 1, wherein the active switching event is the result of a switch operating on the power network.

9. The method of claim 1, wherein the optimal phase angles are spaced 120 degrees apart.

10. The method of claim 1, wherein estimating optimal phase angles for each phase of the power network further comprises:
rotating each of the phase measurements by a rotation angle that places a B-phase value at 180 degrees;
averaging the rotated B-phase value, a rotated A-phase value, and a rotated C-phase value;
determining a new estimate for the B-phase value from the averaged rotated B-phase, A-phase, and C-phase values;
determining a new estimate for the A-phase value and the C-phase value from the new estimate for the B-phase value; and
removing the rotation angle from each of the new estimates.

11. The method of claim 1, where in the correction value is a constant phase error between an approximated voltage and a true voltage.

12. A non-transitory computing device readable medium having instructions stored thereon, wherein the instructions are executable by a processor to cause a computing device to perform a method comprising:
receive current magnitude and phase measurements from a plurality of line monitoring devices prior to an active switching event on the power network;
receive current magnitude and phase measurements from the plurality of line monitoring devices after the active switching event on the power network;
estimate optimal phase angles for each phase of the power network;
determine an error correction value for the phase measurements; and
correct the estimated optimal phase angles for each phase of the power network with the error correction value.

13. A power line monitoring system, comprising:
a plurality of line monitoring devices configured to collect current magnitude and phase measurements for each phase of a power network before and after an active switching event; and
a remote computing device configured to receive the current magnitude and phase measurements from the plurality of line monitoring devices, the remote computing device being configured to:
estimate optimal phase angles for each phase of the power network;
determine an error correction value for the phase measurements; and
correct the estimated optimal phase angles for each phase of the power network with the error correction value.
